(19) United States
(12) Patent Application Publication
(10) Pub. No.: US 2005/0204215 A1
(43) Pub. Date: Sep. 15, 2005

(54) Problem solving in a communications system

(75) Inventor: Juha Tukiainen, Espoo (FI)

Correspondence Address: SQUIRE, SANDERS & DEMPSEY L.L.P., 14TH FLOOR, 8000 TOWERS CRESCENT, TYSONS CORNER, VA, 22182, US

(73) Assignee: Nokia Corporation

(21) Appl. No.: 10/865,816

(22) Filed: Jun. 14, 2004

(30) Foreign Application Priority Data
Feb. 13, 2004 (GB) 0403276.9

(51) Int. Cl. G01R 31/28

(52) U.S. Cl. 714/712

(57) ABSTRACT

A computer system for handling problems encountered by users of a communications network is disclosed. The computer system comprises an input terminal for receiving requests from the users. Each request includes details of a problem. A pipeline receives the requests and processes them at different levels for determining an incremental solution at each tier. A knowledge base stores the request and is updated with the incremental solutions provided by the pipeline, until such time as a sufficient solution is found, which is stored in the knowledge base and returned to the user.

### BACKGROUND OF THE INVENTION

### Field of the Invention

The present invention relates to trouble shooting, that is providing solutions to problems encountered by users of a communications system, in particular, but not exclusively, to a wireless communications network.

### SUMMARY OF THE INVENTION

Technical support systems play a major role in most modern technologically intensive environments. Such functionality could include post-sales service, maintenance and/or repair. Also, depending on the particular product line, for example software, it might be possible to provide quick fixes or work-around solutions to a problematic piece of software.

Technical assistance may be provided in various different forms. For example, a website can be provided having a specific link which deals with after-sales services. Such a website might contain downloadable software fixes, frequently asked questions (FAQ) with answers to commonly occurring problems, an email address for further assistance and/or telephone number to get support from a human agent.

An aim of many modern helpdesk services is to reduce the amount of resources which are necessary to service each request. In particular, each request ties up a considerable amount of resources and therefore there is a trend towards trying to provide helpdesk systems which are largely automatic or provide self-support so that human involvement is kept to a minimum.

In order to achieve such a system it is necessary to build up a knowledge-base that stores potential solutions to problems.

GB 2 386 214 published on 10 Sep. 2003 describes one such system where a helpdesk service has a knowledge base, and wherein a confidence rating is assigned to each potential solution found to a defined problem. If a potential solution is found with a confidence rating greater than a threshold value, then the solution is automatically returned to the user without involving a human agent.

Also, US Application Publication No. 2003/0028513 published on 6 Feb. 2003 describes a system which captures contact information about a user's computing environment, and wherein this contact information is used to locate related help documents in a knowledge base.

Finally, US Application Publication No. 2003/0115087 published on 19 Jun. 2003 has a knowledge base section which stores various claim reports and solutions related to the claim reports.

The present invention seeks to make improvements to a helpdesk service which comprises a knowledge base.

According to one aspect of the present invention there is provided a computer system for handling problems encountered by users of a communications network, the computer system comprising: an input terminal for receiving requests from the users, each request comprising details of a problem; a pipeline connected to receive the requests and having a plurality of tiers each capable of processing the problem at respectively different levels for determining an incremental solution at each tier; a database for storing each request and having storage locations associated with each request for receiving the incremental solutions provided by the pipeline; means for determining at a first one of said tiers if the incremental solution provided by said first tier is a sufficient solution to the problem; and means responsive to the determining means for supplying the incremental solution to at least one of the other tiers for processing in said other tier to generate a next incremental solution.

According to a further aspect of the present invention there is provided a method for handling problems encountered by users of a communications network, the method comprising: receiving requests from the users, each request comprising details of a problem; routing each request to a pipeline having a plurality of tiers each capable of processing the problem at respectively different levels for determining an incremental solution at each tier; storing each request in a database having storage locations associated with each request for receiving the incremental solutions provided by the pipeline; determining at a first one of said tiers if the incremental solution provided by said first tier is a sufficient solution to the problem; and if the incremental solution is not a sufficient solution, supplying the incremental solution to at least one of the other tiers for processing in said other tier to generate a next incremental solution.

For a better understanding of the present invention and to show how the same may be carried into effect, reference will now be made to the accompanying drawings by way of example in which:

### BRIEF DESCRIPTION OF THE DRAWINGS

FIG. 1 shows a physical architecture of an embodiment of the present invention;

FIG. 2 shows a logical architecture of an embodiment of the present invention;

FIG. 3 shows an example of the processes for setting up a record from a user's request;

FIG. 4 shows an example of the trouble-shooting process in each tier according to an embodiment of the present invention; and

FIG. 5 shows an example of the knowledge base of an embodiment of the present invention.

### DETAILED DESCRIPTION OF THE PREFERRED EMBODIMENTS

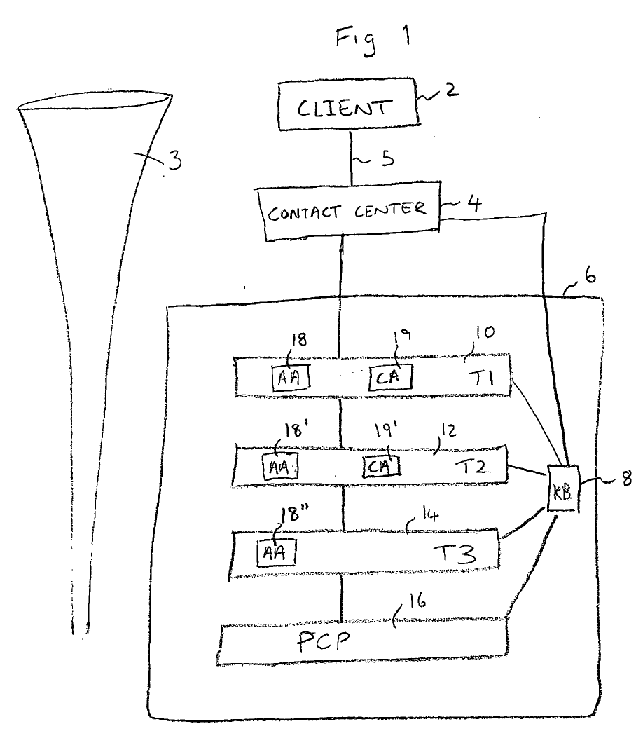

FIG. 1 shows a client terminal 2, which in practice would be a customer, for example a customer of a wireless communication network, for example a network operator or a service provider. The client 2 could also be an individual user who has subscribed to that particular communication network, for example of a network provider, and who are roaming in the network with mobile terminals. Therefore it should be appreciated that the client can take on many different forms, but that the underlying principle remains that the client has a particular problem he needs to solve.

According to the embodiment of FIG. 1 the contact centre is the entry point of the computer system of the present invention. That is, the contact centre 4 is arranged to receive requests from the client 2, to validate the requests and then route the validated requests to a pipeline 6 comprising a plurality of processing tiers 10, 12, 14 and 16. Each request will define the details of the problem experienced by the client and also possibly a list of the symptoms that the client has encountered. It should be appreciated that the client 2 and the contact centre 4 can be implemented in a variety of different ways. For example, in one embodiment the contact centre might simply be a computer terminal which is arranged to autonomously process the request received from the client 2 without a human agent. For example, the client 2 could enter the details of the request online into a request template.

In another embodiment, the contact centre 4 might comprise a human agent which is able to receive a telephone call from a client 2, wherein the client will provide the human agent with details of the problem which is encountered. In turn, the human agent could for example enter these details onto a request template, which would then allow the contact centre to capture the correct product and case information for routing the request to a processing pipeline 6.

It should be appreciated that the interface 5 between the client and the contact centre may either be a wireless interface or a fixed line connection, and in addition is not limited to any particular protocol format. That is, the client can send requests to the contact centre using: email, accessing a website via a URL (Universal Resource Locator), an online chat facility through the internet, instant messaging with either a human operator or a robot (BOT), etc. Also it should be appreciated that the client 2 could take on many different forms, for example: a mobile terminal, a workstation, a PDA (Personal Digital Assistant), etc.

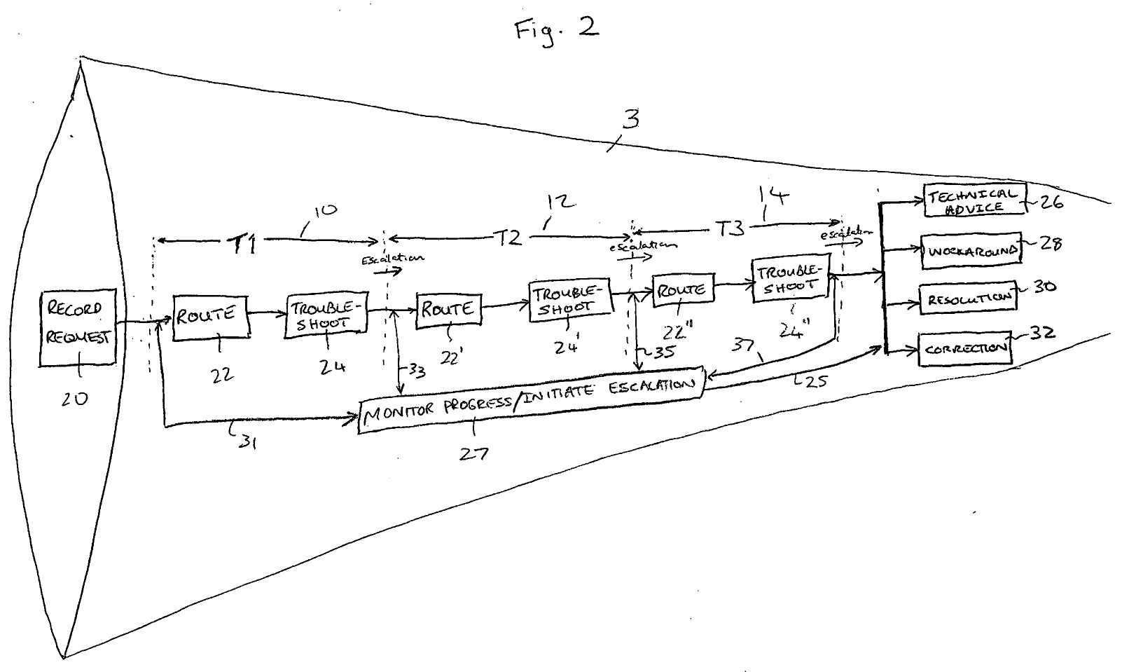

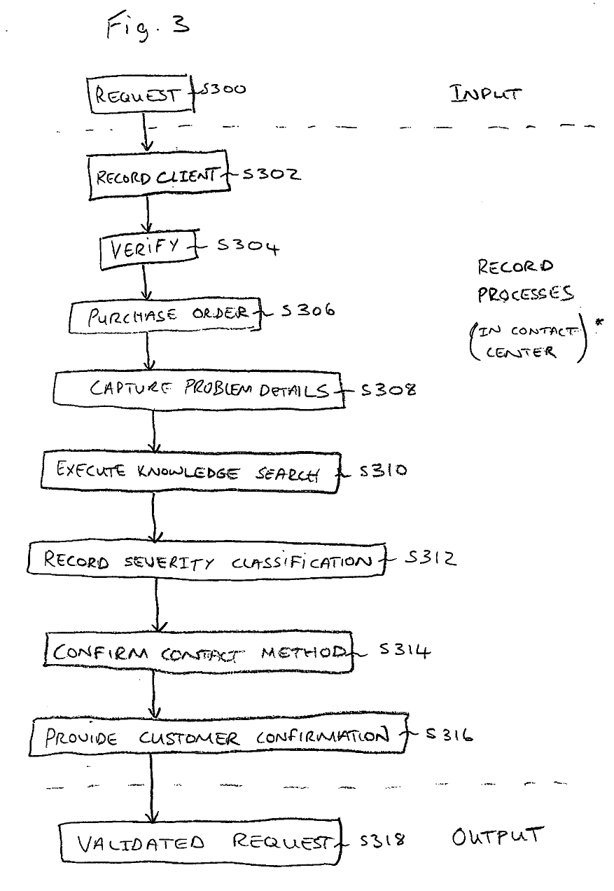

The purpose of the contact centre 4 is to record the request received from the client 2. The recorded request is validated using record processes as described in FIG. 3 and depending on the information contained in the request for a particular user, this request is then routed to the pipeline 6 as shown in FIG. 2.

FIG. 3 shows a flowchart indicating various record processes that are performed according to an embodiment of the present invention. That is FIG. 3 shows at step S300 a request is received at the contact centre 4 from the client 2 and is then processed using steps S302 through S316. However, before describing these processes for obtaining a validated record of the request, it is necessary to briefly describe a knowledge base (KB) 8 which resides in the pipeline 6. It should be appreciated that the knowledge base 8 could reside outside of the pipeline 6 and indeed somewhere else in the communications system as a whole. The important point is that the knowledge base is connected to all of the processing tiers of the pipeline 10, 12, 14, 16 and the contact centre 4. In this way the knowledge base is continuously updated in a dynamic fashion by information generated in one tier so that any information generated in a preceding tier becomes available to an operation executed in a subsequent tier. Each processing tier operates on details of the problem to generate an incremental solution.

FIG. 1 shows a conical shape 3 alongside the system and represents the complexity of the problem as it is received from the client 2 and progresses through the contact centre 4 and the pipeline 6. At the top, the conical shape 3 is at its widest representing the fact that the problem encountered by the client at this stage of processing has many unknowns. The conical shape also represents that the majority of the request can be resolved in the lowest possible tier by using available solutions in the knowledge base 8. As the request proceeds through the contact centre 4 and the pipeline 6, the knowledge base 8 is updated with incremental solutions generated by the processing tiers which reduce the number of unknowns in the original problem.

By way of example, consider a network operator as the client 2, which is experiencing problems with one of its base stations. The network operator is the client 2 and sends a request to the contact centre 4 of the present invention asking for help with his problematic base station. At this point, the problem has many unknowns, for example the product details such as the particular type of base station may not have been included in the request or are not known by the client 2, or other details such as the software version being used may have been omitted. The contact centre then goes through a record process so that all this information is captured and stored to the knowledge base 8 as and when this information is obtained.

The validated request is then routed to the pipeline 6 having a sequential number of tiers for processing different aspects of the problem. That is, the first tier 10 could for example be a centre having local customer knowledge. An example of this might be a specific national region which is familiar with the base stations of the client. FIG. 2 shows that each of the processing tiers incorporates a trouble-shooting element 24, which performs trouble-shooting on the request to try and find a solution or at least an incremental (i.e. partial) solution to the problem encountered by the client. That is, the local customer knowledge centre might be able to solve part of the problem which the client experiences, and therefore will update the database 8 with an incremental solution to the problem, or alternatively if the incremental solution provided by the first tier 10 is sufficient to solve the problem then processing at this tier is stopped and the knowledge base 8 is updated. If a sufficient solution can be found during the processing of tier 1, then the conical shape 3 in FIG. 1 will be truncated at the level of tier 1 indicating that the problem has been solved, the knowledge base is updated and a contact agent 19 uses the updated knowledge base 8 to provide the client with the solution to his problem.

The contact agent 19, 19′ is the block of functionality, shown to exist in either the first or second tiers 10, 12 which is responsible for liasing with the client 2. The contact agent 19, 19′ is responsible for contact with the client during the processing of the request. That is, the contact agent is able to provide technical information about the client's product, answer client questions, provide solutions, etc. It is possible that the contact agent 19, 19′ is a server, for example an email server if the client 2 has purchased a “e-Service”. That is, if the client 2 has opted for the e-service option then the client will be in contact with the system via email only. However, typically the contact agent 19 is a human that exists in the first tier 10 (i.e. close to the client 2) and has technical expertise. However, for certain products the contact agent may be instead in the second tier 12. This depends on the agreement with the client 2.

Typically, however, not all of the problem will have been solved and it is therefore necessary to escalate to a second processing tier 12. For example the second processing tier 12 could be a “specialised technical centre”, which has a more generalised knowledge of base stations, rather than a more specific knowledge of individual customers. Again FIG. 2 shows that the second tier also has its own trouble-shooter 24′ for trying to resolve the problem. The second processing tier 12 is able to draw from the knowledge base which has been dynamically updated with the incremental solution provided by the contact centre 4 and the first tier 10 of the previous steps. Thus using the information provided in the knowledge base 8 the trouble-shooter 24′ tries to solve the outstanding problem encountered by the customer.

In the second tier 12, again if only a partial solution to the problem can be found the knowledge base 8 is updated with the incremental solution provided by the special technical centre and once again the request is escalated to the next tier 14 for further processing. If however, the second tier 12 is able to address the outstanding details of the problem, then the knowledge base is: updated with the sufficient solution, processing is stopped and the solution is returned to the client via the contact agent 19, 19′.

The third tier 14 could for example comprise an “in-depth product knowledge centre”, which would also have its own trouble-shooter 24″. As its name suggests, the third tier 14 would be a centre which has in-depth knowledge of the particular base station in question. Again, the third tier 14 is able to rely on the knowledge base 8, which has been updated with the incremental solutions provided by the previous processing tiers 10 and 12 and other information provided by the contact centre 4. If the third tier is able to provide a solution to a part of the problem which is still outstanding, then the knowledge base 8 is updated appropriately with the sufficient solution, which is also forwarded to the client 2 via the contact agent 19, 19′. If however, the third tier 14 is only able to provide an incremental solution then the database is updated with this incremental solution and the outstanding part of the problem is escalated to the final PCP (Production Creation Process) level 16.

If a particular problem has not been resolved in progressing through the three tiers 10, 12 and 14, this will typically mean that the problem is a fundamental one which will need to be addressed in the actual production cycle, for example the manufacturing process of the base station. In the example, the PCP might be a research and development site, wherein simulations can be performed and/or alterations can be made to the actual manufacturing process of a particular base station. Once the outstanding problem has been resolved it is forwarded to the client via the contact agent 19, 19′.

In summary, FIG. 2 shows a logical architecture of the three processing tiers of the present application. That is, processing tiers shown by its routing elements 22, 22′. 22″ and trouble-shooting elements 24, 24′, 24″ which are used to process the problem request received from the contact centre 4. FIG. 2 also shows a management unit 27 which is responsible for monitoring the progress of the request and for determining when it is necessary to initiate escalation to the next processing tier. That is, the management unit 27 is responsible for monitoring the processing of the problem request and determining at certain points whether to initiate escalation to the next processing tier or to stop processing if the solution has been found.

In more detail, FIG. 2 shows that the management unit receives an input on line 31 and determines whether the validated request 20 is sufficient to solve the problem or whether the problem needs to be routed to the pipeline 6. For simple requests, for example if a client 2 asks whether a base station is still under warranty and provides the serial number, a sufficient solution can be determined in the record process by accessing the knowledge base 8 to determine the required information of whether the base station is or is not still under warranty in which case it is not necessary for the problem to be routed to the pipeline since it has already been solved.

However, for more complicated requests the processing will proceed to tier 1 where a trouble-shooter performs a trouble-shooting operation on the problem and either the problem is totally solved or only partially solved. This is indicated on line 33 to the management unit 27, which decides whether or not the processing is stopped at this point (i.e. for a total solution) or is technically escalated to the next tier 12 for further processing. Likewise, the same decision is made depending on the inputs received on lines 35 and 37 respectively. Finally, the management unit 27 shows that when the complete solution has been provided it can be output on line 25, and wherein the solution to the problem may take various different forms including technical advice 26, a work-around solution 28, resolution of the problem 30, and/or a correction 32.

An active agent 18 is shown to exist within the three processing tiers 10, 12 and 14 shown in FIG. 1. The function of the active agent is to manage the trouble-shooting of the requests and assumes responsibility for processing the request while it remains in its own tier. The active agent is also responsible for determining whether the request needs to be escalated to other tiers.

The knowledge base 8 provides information which is continuously and dynamically updated, which may be reused during later stages of processing. This allows searching of the knowledge base to find solutions which meet a customer's request. That is, on searching through the database it is possible to identify information which is similar to that of the client's request. In this way, the knowledge base enables embodiments of the present invention to find solutions or incremental solutions to problems which have occurred in the past. Thus, the knowledge base makes use of its history in solving other problems to try and find facts or symptoms which are similar to the present problem trying to be solved, and in so doing is able to provide solutions to these problems.

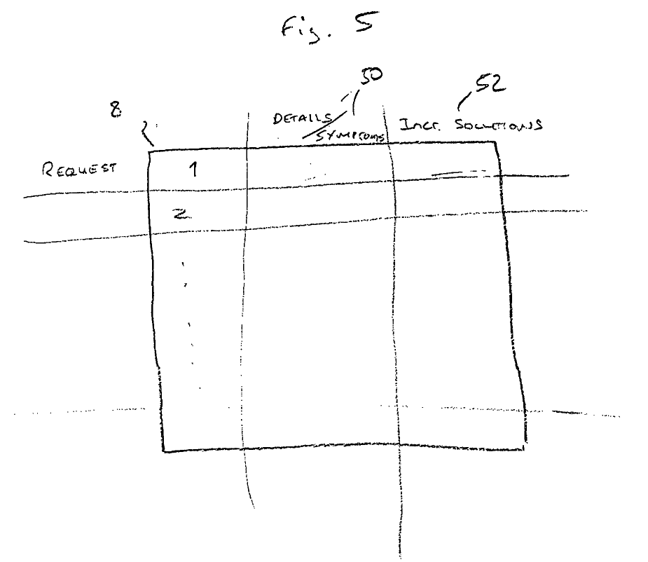

An example of a knowledge base 8 according to an embodiment of the present invention is shown in FIG. 5. The knowledge base comprises a plurality of established requests which have been submitted by other clients 2 in the past, wherein each request storing the details of the request at a particular location 50 and storing an incremental solution (if known) at a particular location 52.

It shall be appreciated that the knowledge base of FIG. 5 is only an example of one embodiment of the present invention. Other embodiments might be that the database also comprises details of the particular client including the version of the equipment that the client is using and other information such as warranty information, site location, etc.

The knowledge base is capable of being searched when the request is being handled by a particular tier. That is, the active agent 18 is capable of scanning the database 8 to check if there are any details 50 in the knowledge base 8 which are the same as those of the request presently being processed. In this way, the knowledge base is able to draw upon previous experience and knowledge, which has been built up by the knowledge base over time. If for example, a request was received three weeks earlier where the details (often referred to as the “symptoms” of the problem) was that an error flag was being raised for a particular transceiver of the base station when operating above a certain bit rate threshold, the database will have stored these details and if an incremental solution was provided for example by changing a particular setting on the RF circuit for that transceiver, then the same incremental solution will work for the current request.

The database may also be searched in a variety of different ways, for example if the details of the request currently being processed by a particular tier, match exactly those stored in the database, then the stored incremental solution 52 will be a sufficient solution and the result can be retuned to the client 2 by way of the contact agent 19, 19′ and processing is halted. However, if there is only a partial match, an existing request in the knowledge base 8 contains many, but not all of the details in the request being processed by a tier, then the incremental solution may only partially solve the problem and the processing will need to be escalated to the next tier to resolve the remainder of the problem.

The searching of a knowledge base may return a plurality of established requests that partially-match (i.e. have most of the details of) the request currently being processed, and in this case, the corresponding incremental solutions for the partially-matched requests are returned to the troubleshooter, which might be able to adapt one of the returned incremental solutions to provide an incremental solution to the request being processed. Moreover, the search of the knowledge base 8 may produce in many partially-matched results which can be rated as to their relevance. These partial matches can also be forwarded on to a laboratory for testing to check their adequacy and again rated. These rating of the partial matched solutions are summarised in a “case summary” (which will be described in more detail later) for troubleshooting in subsequent tiers.

FIG. 3 shows a flow chart of the record process which occurs in the contact center 4 in order to validate a record. The process shows that the input to the process occurs at the step S300, in which a request is received from a client 2. As described the request could typically be entered on an electronic template having certain fields represented by step 302 in which a client record is created.

For example the client record may include the following information: system, network, product, site details, etc.

At step 304, the process verifies whether the client 2 is entitled to make use of the helpdesk system of the present invention by checking if there is a contract with the client or the product is still under warranty. At step 306, it is possible that the client is not entitled, but can be charged for using the help functionality of the system provided that the client pays for it, in which case a purchase order will be generated and forwarded to the client 2 for completion and acceptance.

At step 308 the process may require further information from the client 2 and the client can be asked for further information relating to, for example, the capture of equipment details and versions as well as any symptoms being experienced as a result of the problem. For example, for a computer unit restart it may be necessary to determine what kind of log files are needed and how those are captured.

If the contact centre 4 believes it has sufficient technical expertise to interpret the results of a search of the knowledge base 8, then at step 310 a manual knowledge search of the knowledge base 8 may be conducted using the described symptoms and/or captured system detail provided in step 308, as the search criteria. That is, the system is able to guide the contact centre 4 to ask the correct questions in order to receive the most relevant information related to the request. Any resulting solution(s) are proposed to the client 2. If it is not appropriate to carry out the search of the KB 8 (i.e. not competent), the search will instead be carried out in the first tier 10. Alternatively, if the client 2 has already conducted a search of the knowledge base 8, before submitting the request, then the search results should be manually attached with the request supplied to the contact centre 4. Step S312 checks with the client 2, the severity (or urgency) of the request.

At step 314, the record process establishes the way in which contact will be established with the client 2, for example by email. Also, the process determines the contact points to which information will be supplied, and finally determines the level of information that is supplied to the client 2 as the request progresses through the system. At step 316, the process confirms to the client 2 that a record for their request has been made. This confirmed request or validated record is then routed by way of an output at step 318 to the pipeline 6.

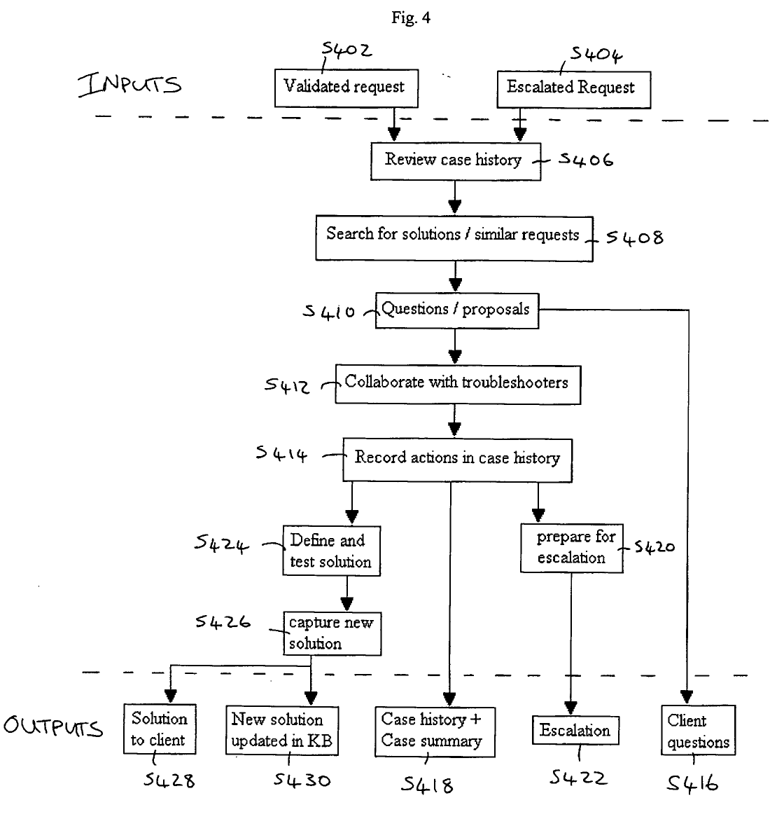

FIG. 4 shows a flow chart of the troubleshoot process which occurs in each of the tiers 10, 12, 14 of the pipeline 6 in order to determine a solution to the problem. The process shows two potential inputs to the process, in which at step S402 one of the tiers can receive a validated request from the contact centre 4, and at step S404 one of them can receive an escalated request from a previous tier.

At step 406, the troubleshooter element 24, 24′, 24″ familiarises itself with the case summary of the request, which provides a summary to the tier currently executing the processing as to the details or processes which have been performed in previous steps including any incremental solutions, and in practice this information can be obtained from the updated knowledge base 8. Thus, the results of any previous research or activities relating to the problem, and related searches of the knowledge base 8 are included in the case summary. This allows the trouble-shooter a more streamlined way of accessing the relevant facts and activities already performed in trying to solve the problem.

Step S408 indicates that the troubleshooter conducts a search of the knowledge base 8 either for potential solutions or other requests having similar details.

At step 410, the troubleshooter process can decide to ask more detailed questions to the client in order to isolate the problem more clearly or may decide to make initial proposals (i.e. solutions) to the client to try and solve the problem. These may be output to the client 2 via the contact center 4 as shown at step 416.

At step S412 it is possible to refer the problem to a “troubleshooting assistant” who is typically a person that is not directly part of the relevant processing tier, but might for example be regarded as a consultant or specialist for that tier, for example R&D developers and/or specialists.

At step S414 all the actions performed in the troubleshoot process are recorded as information in the case history as a case summary. At step S418, the case history and case summary are output to the next tier if escalation is required. That is, before escalation a case summary of the symptoms and activities carried out up to that time is recorded.

S420 indicates that if a sufficient solution cannot be found then the troubleshoot process prepares for escalation to processing by the next tier. Step S22 indicates an output wherein the request is escalated by routing it to the next tier wherein the troubleshoot process is performed again.

S424 shows a step when an incremental solution is designed and tested and confirmed to offer at least a partial solution to the problem. At step S426, this incremental solution is sent to the knowledge base 8 for storage. The output at step S430 indicates that the incremental solution updates the knowledge base 8. Also, the other output at step S428 indicates that the incremental solution can also be passed on to the client 2 via the contact center 4.

In an embodiment of the present invention there is provided a “self-help” facility in that all human agents are removed from the system. In this case, for both the “record” and “troubleshooting” processes, no human agents are needed. For example, if the client 2 has e-Service, no human agents are used. The helpdesk functionality is accessed and controlled by the client 2. For example, the client 2 is able to access a web-site provided at the contact center 4 and complete a template providing the details of the problem. Once completed the details are submitted to the relevant pipeline 6 which will progress through the tiers until a sufficient solution is found, which is then returned to the client 2.

In another embodiment of the present invention, it is also possible to return incremental solutions to the client 2 as and when they are determined as the troubleshooting process progresses through its various tiers 10, 12, 14 and 16. That is, processing during the first tier may not result in a sufficient solution, but may present a plurality of incremental solutions which can be returned to the user who can test whether any of these incremental solutions is sufficient, while the system progresses through its remaining tiers to try and find a sufficient solution.

Thus, the information in the knowledge base 8 is continuously and dynamically updated after each troubleshooting process which allows the following advantages:
Enables easy searching of the knowledge base to find known solutions or similar details relevant to a customer request
Captures and verify new solutions, which can be re-used by other customers, selected partners and internal support pipe engineers.
Manages the knowledge base to ensure that information is always available, valid and useful.
Enables self-help for NET customers.

The applications of the re-useable knowledge base of the present invention find the following applications:
For record processes:
   Used by clients 2 in order to describe the problem promptly
   Used by contact centres 4 in order to ask relevant questions from customers for describing the problem promptly
For troubleshooting processes:
   Used by the active agents 18, 18′, 18″ in the processing tiers 10, 12 and 14 for finding solutions to clients request
   Used by the active agents 18, 18′, 18″ in the processing tiers 10, 12 and 14 when escalating the request to the upper tiers or the PCP layer and including the case summary for subsequent tiers.
Manage knowledge
   Used to accept and validate requests.

In practice various technologies may be used for example Electra™ can be used to provide a summarised case history for each request during processing.

The embodiment of the present invention also provide the following advantages:
guidance to the client 2 for answering more product specific questions in the request template as a result of the details and symptoms processed in the record process.
Gathering and building on incremental solutions and in the troubleshoot processes, analysing these and providing a case summary for escalation to the next tier.
verifying records, for example entitlement testing solutions generated internally in the troubleshoot process and data screening, for example “the solution from a knowledge base search was tested but it did not help”, or “these activities were carried out and excluded as possible causes of the problem”.
enables knowledge gathering and re-use of this knowledge in the troubleshoot process.
enables the creation of new solutions with less effort.
increases the volume of useable cases (i.e. those requests for which case summaries have been provided) in the knowledge base for internal high expertise use.

1. A computer system for handling problems encountered by users of a communications network, the computer system comprising:
an input terminal for receiving requests from users, wherein each request comprises details of a problem;
a pipeline connected to receive the requests and having a plurality of tiers, wherein each tier is capable of processing the problem at respectively different levels for determining an incremental solution at the each tier;
a database for storing the each request and having storage locations associated with the each request for receiving incremental solutions provided by the pipeline; and
determining means for determining at a first tier of said plurality of tiers if the incremental solution provided by said first tier comprises a sufficient solution to the problem; and
supplying means responsive to the determining means for supplying the incremental solution to at least one other tier of said plurality of tiers for processing in said at least one other tier to generate a next incremental solution.

2. The computer system of claim 1, wherein the each tier of the plurality of tiers comprises a troubleshooting device responsible for managing the processing of the problem at the each tier.

3. The computer system of claim 2, wherein the troubleshooting device determines the incremental solution for the each tier by searching the database for at least one incremental solution corresponding to the details matching the each request.

4. The computer system of claim 1, further comprising at least one tier of the plurality of tiers comprising a contact agent for returning the incremental solution to a user if it comprises the sufficient solution to the problem.

5. The computer system of claim 4, wherein the contact agent comprises a human agent.

6. The computer system of claim 4, wherein the contact agent comprises a computer.

7. The computer system of claim 1, wherein the plurality of tiers includes different levels of complexity for processing the problem, in which the first tier comprises the least complex tier.

8. The computer system of claim 1, wherein the each tier of the plurality of tiers is connected to access the incremental solution stored in the database which corresponds to another request.

9. The computer system of claim 1, wherein the database is updated dynamically so that for a same request, in which a subsequent tier uses the incremental solution provided by a previous tier.

10. The computer system of claim 1, wherein the each tier provides a summary of all relevant processing activities performed, for use by the next tier.

11. The computer system of claim 1, wherein the processing is halted when the sufficient solution is determined.

12. The computer system of claim 11, wherein the sufficient solution is determined by as few of those tiers of the plurality of tiers as is required.

13. The computer system of claim 1, wherein the sufficient solution returned to a user comprises at least one of
technical advice;
a workaround;
a resolution; and
a correction.

14. The computer system of claim 1, wherein the communications network comprises a wireless communications network

15. A system for handling problems encountered by users of a communications network, the system comprising:
receiving means for receiving requests from users, wherein each request comprises details of a problem;
routing means for routing the each request to a pipeline having a plurality of tiers, wherein each tier of the plurality of tiers processes the problem at respectively different levels for determining an incremental solution at the each tier;
storing means for storing the each requests in a database having storage locations associated with the each request for receiving the incremental solution provided by the pipeline;
determining means for determining at a first tier of said plurality of tiers if the incremental solution provided by said first tier comprises a sufficient solution to the problem; and
supply means for supplying the incremental solution to an other tier of the plurality of tiers for processing in said other tier to generate a next incremental solution if the incremental solution does not comprise the sufficient solution.

16. A method for handling problems encountered by users of a communications network, the method comprising:
receiving requests from users, wherein each request comprises details of a problem;
routing the each request to a pipeline having a plurality of tiers, wherein each tier of the plurality of tiers processes the problem at respectively different levels for determining an incremental solution at the each tier;
storing the each request in a database having storage locations associated with the each request for receiving the incremental solution provided by the pipeline;
determining at a first tier of said plurality of tiers if the incremental solution provided by said first tier comprises a sufficient solution to the problem; and
supplying the incremental solution to another tier of the plurality of tiers for processing in said other tier to generate a next incremental solution if the incremental solution does not comprise the sufficient solution.

17. The method of claim 16, further comprising:
receiving the sufficient solution to the problem at a client without human intervention.
